(19) United States
(12) Patent Application Publication
(10) Pub. No.: US 2026/0262347 A1
(43) Pub. Date: Sep. 3, 2026

(54) LIGHT-EMITTING ELEMENT AND DISPLAY APPARATUS

(71) Applicant: SAMSUNG ELECTRONICS CO., LTD., Suwon-si (KR)

(72) Inventors: Koji MURATA, Yokohama-shi (JP); Dohoon KIM, Yokohama-shi (JP); Eiji HASEGAWA, Yokohama-shi (JP); Kazuyuki ISHIKAWA, Yokohama-shi (JP)

(73) Assignee: SAMSUNG ELECTRONICS CO., LTD., Suwon-si (KR)

(21) Appl. No.: 19/635,013

(22) Filed: Mar. 31, 2026

Related U.S. Application Data
(63) Continuation of application No. PCT/KR2026/002298, filed on Feb. 6, 2026.

(30) Foreign Application Priority Data
Feb. 28, 2025 (JP) 2025-031038

(51) Int. Cl. H10H 20/851

(52) U.S. Cl. CPC H10H 20/8513

(57) ABSTRACT

Provided are a light-emitting element and a display apparatus, each of which may extract more wavelength-converted light. The light-emitting element may include a light source for emitting light in a first wavelength region, and a wavelength conversion layer including a wavelength conversion material for converting light in the first wavelength region into light in a second wavelength region, and a plurality of single-crystal silicon particles for scattering light in the first wavelength region.

### CROSS-REFERENCE TO RELATED APPLICATIONS

This application is a continuation application of International Application No. PCT/KR2026/002298, filed on Feb. 6, 2026, which is based on and claims priority to Japanese Patent Application No. 2025-031038, filed on Feb. 28, 2025, in the Japan Patent Office, the disclosures of which are incorporated by reference herein in their entireties.

### BACKGROUND

### 1. Field

The present disclosure relates to a light-emitting element and a display apparatus.

### 2. Description of Related Art

Recently, a light-emitting element having a wavelength conversion layer is being developed. In the light-emitting element, a wavelength of light emitted from a light source may be converted by the wavelength conversion layer and extracted to the outside. The wavelength conversion layer may include, for example, titanium oxide particles together with quantum dots (for example, Patent Document 1). The light-emitting element may be applied to, for example, a display apparatus or a lighting apparatus.

### SUMMARY

It is useful for a light-emitting element and a display apparatus, each of which includes a wavelength conversion layer, to extract more wavelength-converted light.

The present disclosure provides a light-emitting element and a display apparatus, each of which may extract more wavelength-converted light.

According to an aspect of the disclosure, there is provided a light-emitting element including: a light source configured to emit light in a first wavelength region; and a wavelength conversion layer including: a wavelength conversion material configured to convert light in the first wavelength region into light in a second wavelength region; and a plurality of single-crystal silicon particles configured to scatter light in the first wavelength region.

The second wavelength region may be a red wavelength region, and wherein a single-crystal silicon particle, from among the plurality of single-crystal silicon particles, has a size greater than or equal to 90 nm o and less than or equal to 130 nm.

The second wavelength region may be a green wavelength region, and wherein

a single-crystal silicon particle, from among the plurality of single-crystal silicon particles, has a size greater than or equal to 80 nm and less than or equal to 110 nm.

The first wavelength region may be a blue wavelength region.

The wavelength conversion material may include at least one of quantum dots or phosphors.

According to an aspect of the disclosure, there is provided a display apparatus including: a light source provided in each of a first pixel and a second pixel, each light source being configured to emit light in a first wavelength region; a first wavelength conversion layer provided in the first pixel, and including a first wavelength conversion material configured to convert light in the first wavelength region into light in a second wavelength region, and a plurality of first single-crystal silicon particles configured to scatter light in the first wavelength region; and a second wavelength conversion layer provided in the second pixel, and including a second wavelength conversion material configured to convert light in the first wavelength region into light in a third wavelength region different from the second wavelength region, and a plurality of second single-crystal silicon particles configured to scatter light in the first wavelength region.

A particle size D1 corresponding to a first particle size distribution peak of the plurality of first single-crystal silicon particles and a particle size D2 corresponding to a second particle size distribution peak of the plurality of second single-crystal silicon particles may be different from each other.

A peak wavelength in the third wavelength region may be shorter than a peak wavelength in the second wavelength region, and wherein the particle size D2 may be smaller than the particle size D1.

The first wavelength region may be a blue wavelength region, the second wavelength region may be a red wavelength region, and the third wavelength region may be a green wavelength region.

A light source may be provided in a third pixel, further including a plurality of third single-crystal silicon particles for scattering light in the first wavelength region.

Each light source may include a micro light-emitting diode (LED).

According to an aspect of the disclosure, there is provided a lighting apparatus including: a first wavelength conversion layer provided in a first pixel, and including a first wavelength conversion material configured to convert light in a first wavelength region into light in a second wavelength region, and a plurality of first single-crystal silicon particles configured to scatter light in the first wavelength region; and a second wavelength conversion layer provided in a second pixel, and including a second wavelength conversion material configured to convert light in the first wavelength region into light in a third wavelength region different from the second wavelength region, and a plurality of second single-crystal silicon particles configured to scatter light in the first wavelength region.

The lighting apparatus may include a transparent layer including a plurality of third single-crystal silicon particles.

A particle size D1 corresponding to a first particle size distribution peak of the plurality of first single-crystal silicon particles and a particle size D2 corresponding to a second particle size distribution peak of the plurality of second single-crystal silicon particles may be different from each other.

A peak wavelength in the third wavelength region may be shorter than a peak wavelength in the second wavelength region, and wherein the particle size D2 may be smaller than the particle size D1.

The first wavelength region may be a blue wavelength region, the second wavelength region may be a red wavelength region, and the third wavelength region may be a green wavelength region.

The lighting apparatus may include a plurality of third single-crystal silicon particles for scattering light in the first wavelength region.

### BRIEF DESCRIPTION OF THE DRAWINGS

The above and other aspects and/or features of embodiments of the disclosure will become more apparent from the following detailed description taken in conjunction with the accompanying drawings, in which:

FIG. 1 is a cross-sectional view showing an example of a configuration of a display apparatus according to an embodiment;

FIG. 2A is a cross-sectional view showing an example of a configuration of a red conversion layer shown in FIG. 1;

FIG. 2B is a cross-sectional view showing an example of a configuration of a green conversion layer shown in FIG. 1;

FIG. 3A is a diagram for describing light extracted from the red conversion layer shown in FIG. 1;

FIG. 3B is a diagram for describing light extracted from a red conversion layer according to a comparative example;

FIG. 4 is a diagram showing examples of scattering spectra of first single-crystal silicon particles shown in FIG. 3A and titanium oxide particles shown in FIG. 3B;

FIG. 5 is a diagram showing other examples of scattering spectra of the first single-crystal silicon particles shown in FIG. 3A and the titanium oxide particles shown in FIG. 3B; and

FIG. 6 is a cross-sectional view showing an example of a configuration of a transparent layer in a display apparatus according to a modified example.

### DETAILED DESCRIPTION

Below, one or more embodiments of the present disclosure are described in detail with reference to the accompanying drawings. In the drawings shown below, the same reference numerals refer to the same components, and the size of each component in the drawings may be exaggerated for clarity and convenience of description. An embodiment described below is merely exemplary, and various modifications are possible from the embodiment.

In the following description, if a component is referred to as being “on” or “above” another component, the component may be directly “on” another component in contact or “above” another component without contact. Similarly, if a component is referred to as being “beneath” or “below” another component, the component may be directly “beneath” another component in contact or “below” another component without contact.

A term of a singular number may include its plural number unless explicitly indicated otherwise in the context. In addition, if a component is described as “including”, “comprising”, or “having” another component, it does not exclude a case where the corresponding component includes other components unless otherwise specifically stated, but rather indicates that the corresponding component may further include other components.

For steps included in a method, if an order is explicitly described, or if there is no description to the contrary, the steps may be executed in an appropriate order. The execution of the steps is not necessarily limited to the order in which the steps are described. Any use of examples or exemplary terms is intended merely to describe the spirit of the present disclosure, and the scope of the present disclosure is not limited by the examples or exemplary terms unless otherwise defined in the claims.

In addition, in the following description, ordinal numerals such as “first” and “second” may be used for convenience, and unless specifically stated otherwise, do not indicate any particular order.

### Embodiment

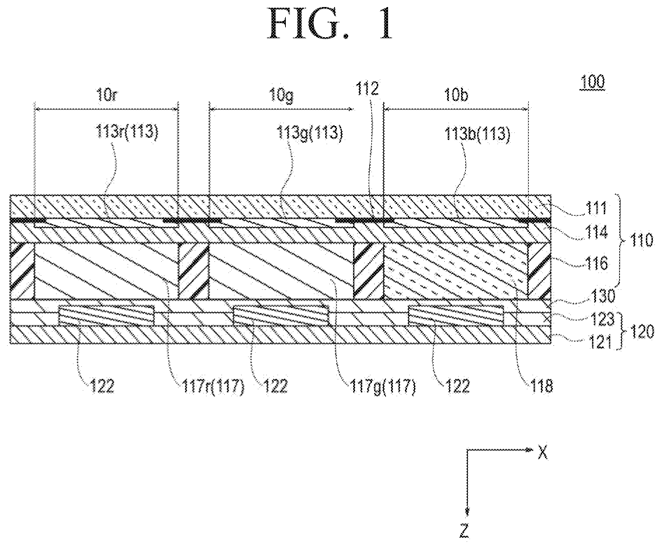

FIG. 1 shows an example of a cross-sectional configuration of a display apparatus (i.e., a display apparatus 100) according to an embodiment. The display apparatus 100 may include, for example, a first structure 110, a second structure 120, and a joint layer 130. In the display apparatus 100, for example, the second structure 120 and the first structure 110 may be stacked, and the joint layer 130 may be disposed (or provided) therebetween. The second structure 120 may include a light source 122. Light emitted from the light source 122 may sequentially pass through the joint layer 130 and the first structure 110, and be extracted to the outside of the display apparatus 100. The light source 122 may emit, for example, light in a blue wavelength region (for example, 430 nm to 495 nm).

In this display apparatus 100, a plurality of red pixels 10r, a plurality of green pixels 10g, and a plurality of blue pixels 10b may be disposed in a matrix form. Light in a red wavelength region (e.g., 600 nm to 750 nm) may be extracted from the red pixel 10r, light in a green wavelength region (e.g., 495 nm to 570 nm) may be extracted from the green pixel 10g, and light in the blue wavelength region may be extracted from the blue pixel 10b. In the following description, a stacking direction of the second structure 120 and the first structure 110 may be a Z direction, and an arrangement direction of the red pixel 10r, the green pixel 10g, and the blue pixel 10b may be an X direction and a Y direction.

### <Configuration of Display Apparatus 100>

### (First Structure 110)

The first structure 110 may include, for example, a transparent substrate 111, a light-shielding matrix 112, a color filter 113, an overcoat layer 114, a partition wall 116, a color conversion layer 117, and a transparent layer 118. The color filter 113 may include, for example, a red color filter 113r, a green color filter 113g, and a blue color filter 113b. The color conversion layer 117 may include, for example, a red conversion layer 117r and a green conversion layer 117g.

In the red pixel 10r, the transparent substrate 111, the red color filter 113r, the overcoat layer 114, and the red conversion layer 117r may be sequentially disposed in the Z direction. In the green pixel 10g, the transparent substrate 111, the green color filter 113g, the overcoat layer 114, and the green conversion layer 117g may be sequentially disposed in the Z direction. In the blue pixel 10b, the transparent substrate 111, the blue color filter 113b, the overcoat layer 114, and the transparent layer 118 may be sequentially disposed in the Z direction.

The transparent substrate 111 may be, for example, a plate-shaped member having a rectangular planar (XY plane) shape. The transparent substrate 111 may have light transparency. The transparent substrate 111 may include, for example, a glass material or a resin material. The resin material may be, for example, polyimide. The transparent substrate 111 may have plasticity.

The light-shielding matrix 112 may also be referred to as a black matrix. The light-shielding matrix 112 may be disposed, for example, between one main surface of the transparent substrate 111 and the overcoat layer 114 together with the color filter 113. The light-shielding matrix 112 may serve to prevent color mixing between light respectively emitted from the red pixel 10r, the green pixel 10g, and the blue pixel 10b. The light-shielding matrix 112 may be disposed, for example, between the red color filter 113r and the green color filter 113g, between the green color filter 113g and the blue color filter 113b, and between the blue color filter 113b and the red color filter 113r. An end of the light-shielding matrix 112 may overlap an end of the color filter 113. The light-shielding matrix 112 may include a patternable light-shielding material.

The color filter 113 can selectively transmit light in a predetermined wavelength region. The red color filter 113r can selectively transmit light in the red wavelength region. The green color filter 113g can selectively transmit light in the green wavelength region. The blue color filter 113b can selectively transmit light in the blue wavelength region. The color filter 113 may be disposed as described above, thereby increasing color purity of light extracted from each of the red pixel 10r, the green pixel 10g, and the blue pixel 10b. The color filter 113 can include, for example, the resin material.

The overcoat layer 114 may be disposed between the color filter 113 and the color conversion layer 117 or the transparent layer 118. The overcoat layer 114 may also be disposed between the light-shielding matrix 112 and the partition wall 116. The overcoat layer 114 may serve to planarize the main surface of the transparent substrate 111 on which the light-shielding matrix 112 and the color filter 113 are disposed, and simultaneously protect the color filter 113. The overcoat layer 114 may include, for example, a photosensitive acrylic resin. The overcoat layer 114 may have, for example, a refractive index of about 1.5.

The partition wall 116 may partition the red pixel 10r, the green pixel 10g, and the blue pixel 10b from one another. A height of the partition wall 116 (or its size in the Z direction) may approximately be the same as a thickness of the red conversion layer 117r, the green conversion layer 117g, or the transparent layer 118. The height of the partition wall 116 may be, for example, 5 μm or more and 50 μm or less. The partition wall 116 may have a light reflection characteristic for light in a wavelength region emitted from the light source 122 and light in a wavelength region converted by the red conversion layer 117r or the green conversion layer 117g. Accordingly, the partition wall 116 may reflect light emitted directly from the light source 122 or emitted from the light source 122 through the red conversion layer 117r or the green conversion layer 117g toward the partition wall 116. Accordingly, utilization efficiency of the light emitted from the light source 122 may be increased, and extraction efficiency of light may be enhanced. The partition wall 116 may include, for example, a white pigment or the resin material. A photosensitive resin material such as an acrylic resin, an epoxy resin, a silicone resin, or a polyimide resin may be used as the resin material.

The color conversion layer 117 disposed in the red pixel 10r or the green pixel 10g can convert the wavelength of light incident from the second structure 120 and transmit light to the transparent substrate 111.

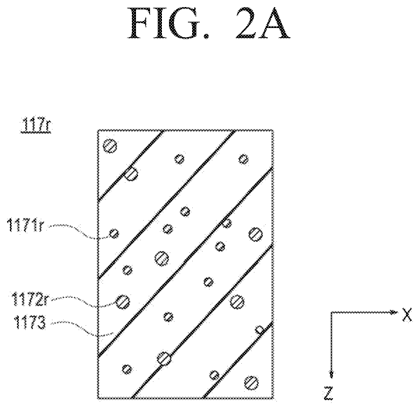

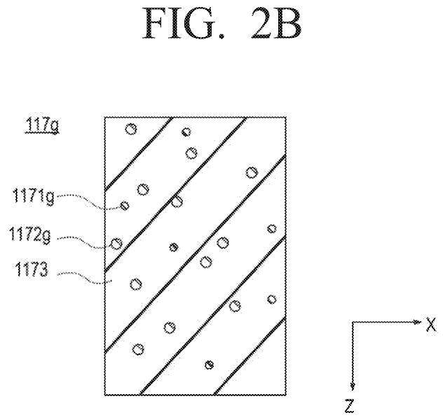

FIG. 2A shows an example of a configuration of the red conversion layer 117r, and FIG. 2B shows an example of a configuration of the green conversion layer 117g. The red conversion layer 117r disposed in the red pixel 10r may include, for example, a first wavelength conversion material 1171r, first single-crystal silicon particles 1172r, and a binder 1173. The green conversion layer 117g disposed in the green pixel 10g may include, for example, a second wavelength conversion material 1171g, second single-crystal silicon particles 1172g, and the binder 1173.

The first wavelength conversion material 1171r or the second wavelength conversion material 1171g may be, for example, a phosphor or quantum dots. In other words, each of the first wavelength conversion material 1171r and the second wavelength conversion material 1171g may include at least one of the phosphor or the quantum dots. The first wavelength conversion material 1171r may convert a wavelength of light emitted from the light source 122 into the red wavelength region. The first wavelength conversion material 1171r included in the red conversion layer 117r may have, for example, a concentration of 5 weight percent (wt %) to 50 wt %. The second wavelength conversion material 1171g may convert the wavelength of light emitted from the light source 122 into the green wavelength region. The second wavelength conversion material 1171g included in the green conversion layer 117g may have, for example, a concentration of 5 wt % to 70 wt %.

In the red conversion layer 117r, the plurality of first single-crystal silicon particles 1172r may be dispersed in the binder 1173. The first single-crystal silicon particle 1172r may include single crystal silicon (c-Si). The first single-crystal silicon particle 1172r may have, for example, a spherical shape. A particle size D1 corresponding to a particle size distribution peak of the plurality of first single-crystal silicon particles 1172r may be, for example, 90 nm or more and 130 nm or less. The first single-crystal silicon particles 1172r included in the red conversion layer 117r may have, for example, a concentration of 0.5 wt % to 15 wt %.

In the green conversion layer 117g, the plurality of second single-crystal silicon particles 1172g may be dispersed in the binder 1173. The second single-crystal silicon particles 1172g may include the single crystal silicon. The second single-crystal silicon particles 1172g may have, for example, the spherical shape. A particle size D2 corresponding to a particle size distribution peak of the plurality of second single-crystal silicon particles 1172g may be different from the size D1. As described in detail below, due to this configuration, scattering of light in the red wavelength region in the red conversion layer 117r or scattering of light in the green wavelength region in the green conversion layer 117g may be easily suppressed.

The size D2 may be smaller than the size D1. The size D2 may be, for example, 80 nm or more and 110 nm or less. For example, if the size D1 is 100 nm, the size D2 may be 90 nm. For example, if the size D1 is 90 nm, the size D2 may be 80 nm. For example, if the size D1 is 130 nm, the size D2 may be 110 nm. The second single-crystal silicon particles 1172g included in the green conversion layer 117g may have, for example, a concentration of 0.5 wt % to 15 wt %.

The binder 1173 included in each of the red conversion layer 117r and the green conversion layer 117g may include the resin material such as the silicone-based resin, the epoxy-based resin, or the acrylic-based resin.

The transparent layer 118 disposed in the blue pixel 10b can transmit light emitted from the light source 122 to the transparent substrate 111 at a high transmittance. The transparent layer 118 can transmit light emitted from the light source 122, for example, at a transmittance of 70% or more. The transparent layer 118 can include, for example, the resin material. For example, the single-crystal silicon particle may not be included in the transparent layer 118.

### (Second Structure 120)

The second structure 120 may include, for example, a thin film transistor (TFT) substrate 121, the light source 122, and an anisotropic conductive film 123.

The TFT substrate 121 may be disposed to face the transparent substrate 111 in the Z direction. The TFT substrate 121 may be a substrate for driving the light source 122 and may include, for example, a base material, a wiring layer disposed on the base material, and a TFT. The wiring layer may have another driving element instead of the TFT. Alternatively, the display apparatus 100 may use a passive matrix driving method.

The plurality of light sources 122 may be disposed on the TFT substrate 121. The light sources 122 may be disposed below each of the red pixel 10r, the green pixel 10g, and the blue pixel 10b. The light source 122 may include, for example, a micro light-emitting diode (LED). The light source 122 may have, for example, a rectangular planar (XY plane) shape. One side of the rectangle may have, for example, a size of 1 μm or more and 100 μm or less. The light source 122 may have a three-dimensional shape, for example, an approximately rectangular parallelepiped or an approximately cubic shape. The light source 122 may include, for example, a gallium nitride (GaN)-based semiconductor material, and may emit light in the blue wavelength region. The anisotropic conductive film 123 may be disposed on the TFT substrate 121 together with the plurality of light sources 122. Here, a structure including the light source 122 and the red conversion layer 117r or a structure including the light source 122 and the green conversion layer 117g may correspond to a specific embodiment of the light-emitting element according to the present disclosure.

### (Joint Layer 130)

The joint layer 130 disposed between the first structure 110 and the second structure 120 can join the first structure 110 to the second structure 120. A thickness of the joint layer 130 (or its size in the Z direction) can be, for example, 5 μm or less. The joint layer 130 can include a pressure-sensitive adhesive, an adhesive, or the like. The joint layer 130 may include, for example, a transparent epoxy resin or the silicone resin.

### <Manufacturing Method of Display Apparatus 100>

Next, the manufacturing method of a display apparatus 100 is described.

The first structure 110 can be manufactured, for example, as described below. First, the light-shielding matrix 112 and the color filter 113 can be sequentially formed on the transparent substrate 111. In forming the color filter 113, the red color filter 113r can be formed in the red pixel 10r, the green color filter 113g can be formed in the green pixel 10g, and the blue color filter 113b can be formed in the blue pixel 10b. Next, the overcoat layer 114 can be formed on the transparent substrate 111 by covering the light-shielding matrix 112 and the color filter 113.

Next, the partition wall 116 can be formed on the overcoat layer 114 by using a photolithography process. Next, the color conversion layer 117 and the transparent layer 118 can be formed in a region surrounded by the partition wall 116. As a result, the first structure 110 may be formed.

In forming the color conversion layer 117, the red conversion layer 117r may contain the first wavelength conversion material 1171r and the plurality of first single-crystal silicon particles 1172r, and the green conversion layer 117g may contain the second wavelength conversion material 1171g and the plurality of second single-crystal silicon particles 1172g.

The plurality of first single-crystal silicon particles 1172r each having the particle size distribution peak at the size D1 and the plurality of second single-crystal silicon particles 1172g each having the particle size distribution peak at the size D2 can be formed, for example, as follows.

First, silicon monoxide (SiO) may be thermally decomposed to obtain a single-crystal silicon particle having a particle size in a nanometer range. In detail, lump-shaped silicon monoxide may be heat-treated at 1450° C. to 1550° C. under a nitrogen atmosphere, and the n solvent replacement can be performed using hydrofluoric acid etching methanol.

Next, a particle of a predetermined particle-size range can be extracted from the obtained single-crystal silicon particle. For example, density gradient centrifugation can be used for this extraction.

The second structure 120 can be manufactured, for example, as described below. First, the TFT substrate 121 can be formed. The light source 122 and the anisotropic conductive film 123 can then be formed on the TFT substrate 121.

The first structure 110 and the second structure 120 can be formed, and the first structure 110 and the second structure 120 can then be joined to each other as described below. First, a joining material to serve as the joint layer 130 can be coated on the second structure 120. Next, the first structure 110 may be positioned and overlapped on a surface of the second structure 120 on which the join material is coated. Next, under a reduced pressure, pressure can be applied to bring the first structure 110 and the second structure 120 to be closer to each other. The joint layer 130 can then be formed by applying energy such as heat or ultraviolet rays to the joining material to cure the same. For example, the display apparatus 100 having a full-color display can be manufactured in this way.

### <Effect of Display Apparatus 100>

In the display apparatus 100, for example, light in the blue wavelength region may be emitted from the light source 122 disposed in each of the red pixel 10r, the green pixel 10g, and the blue pixel 10b, and may pass through the joint layer 130. In the red pixel 10r, light passing through the joint layer 130 may be incident on the red conversion layer 117r, and converted into light in the red wavelength region by the first wavelength conversion material 1171r. The light in the red wavelength region may sequentially pass through the overcoat layer 114, the red color filter 113r, and the transparent substrate 111. In the green pixel 10g, light passing through the joint layer 130 may be incident on the green conversion layer 117g, and converted into light in the green wavelength region by the second wavelength conversion material 1171g. Light in the green wavelength region can sequentially pass through the overcoat layer 114, the green color filter 113g, and the transparent substrate 111. In the blue pixel 10b, light emitted from the light source 122 can sequentially pass through the joint layer 130, the transparent layer 118, the overcoat layer 114, the blue color filter 113b, and the transparent substrate 111.

In the display apparatus 100 according to an embodiment, the red conversion layer 117r may include the plurality of first single-crystal silicon particles 1172r, and the green conversion layer 117g may include the plurality of second single-crystal silicon particles 1172g. The first single-crystal silicon particles 1172r and the second single-crystal silicon particles 1172g may selectively scatter light in the blue wavelength region. Accordingly, more light in the red wavelength region can be extracted from the red pixel 10r, and more light in the green wavelength region can be extracted from the green pixel 10g, respectively. Hereinafter, this operational effect is described using a comparative example.

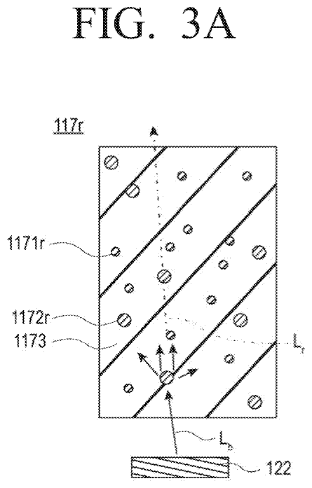

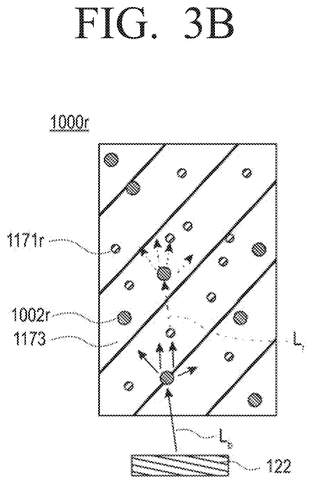

FIG. 3A shows a configuration of the red conversion layer 117r according to an embodiment, and FIG. 3B may shows a configuration of a red conversion layer 1000r according to the comparative example. The red conversion layer 1000r according to the comparative example does not include the single-crystal silicon particle. The red conversion layer 1000r may include the first wavelength conversion material 1171r and a plurality of titanium oxide (TiO₂) particles 1002r.

The titanium oxide particle 1002r may have, for example, the spherical shape. The titanium oxide particle 1002r may have, for example, a particle size of 100 nm to 130 nm. The titanium oxide particle 1002r may have, for example, a refractive index of 2.7. The first single-crystal silicon particle 1172r or the second single-crystal silicon particles 1172g may have a refractive index greater than the refractive index of the titanium oxide particle 1002r, and may have, for example, a refractive index of 4.

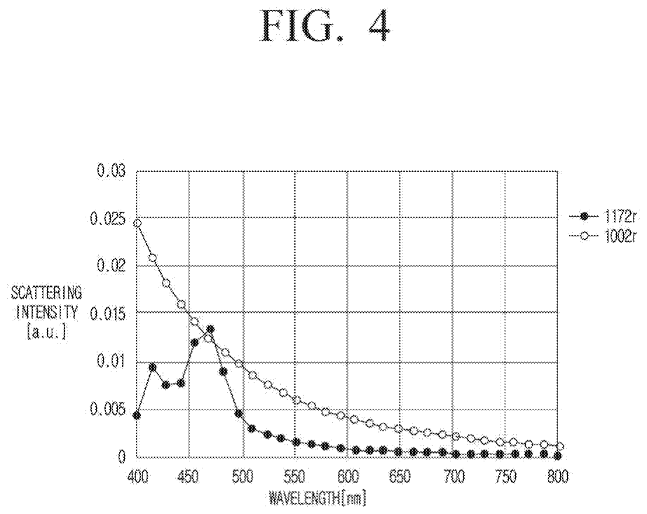

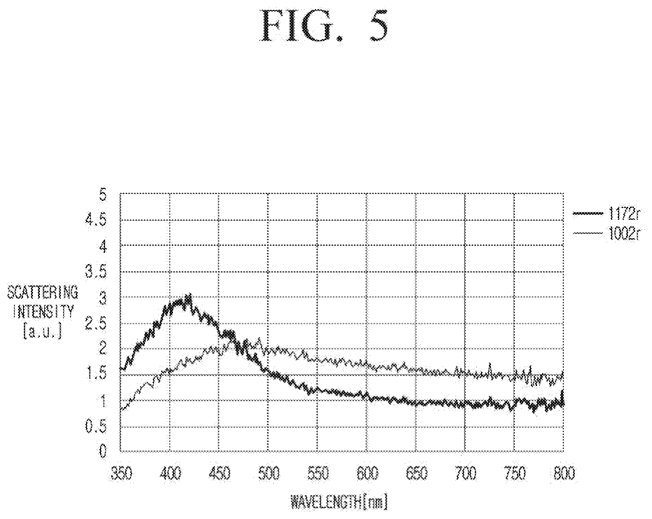

FIGS. 4 and 5 show examples of scattering spectra of the titanium oxide particle 1002r having a particle size of 130 nm and the first single-crystal silicon particle 1172r having a particle size of 100 nm. FIG. 4 shows a finite-difference time-domain (FDTD) simulation result, and FIG. 5 shows an actual measurement value. As shown in FIGS. 4 and 5, compared to the titanium oxide particles 1002r, light in the blue wavelength region may be selectively scattered in the first single-crystal silicon particles 1172r.

Table 1 below shows simulation results of scattering intensity ratios of the titanium oxide particle 1002r having a particle size of 100 nm and the first single-crystal silicon particle 1172r having a particle size of 100 nm. Light in the blue wavelength region (wavelength of about 450 nm) or light in the red wavelength region (wavelength of about 650 nm) shows a scattering intensity ratio of 21% in the titanium oxide particles 1002r and a scattering intensity ratio of 5% in the first single-crystal silicon particles 1172r.

TABLE 1

| | Scattering intensity ratio |
|---|---|
| | (650 nm/450 nm) |
| First single-crystal silicon particle | 5% |
| Titanium oxide particle | 21% |

Table 2 below shows simulation results of scattering intensity ratios of titanium oxide particle 1002r having the particle size of 100 nm and the second single-crystal silicon particle 1172g having a particle size of 90 nm. Light in the blue wavelength region (wavelength of about 450 nm) or light in the green wavelength region (wavelength of about 550 nm) shows a scattering intensity ratio of 43% in the titanium oxide particle 1002r and a scattering intensity ratio of 10% in the second single-crystal silicon particle 1172g.

TABLE 2

| | Scattering intensity ratio |
|---|---|
| | (550 nm/450 nm) |
| second single-crystal silicon particle | 10% |
| Titanium oxide particle | 43% |

In this way, not only light L_{b} in the blue wavelength region but also light Lᵣ in the red wavelength region may be scattered in the titanium oxide particles 1002r. Accordingly, in the red conversion layer 1000r according to the comparative example, not only light L_{b} in the blue wavelength region L_{b} but also light Lᵣ in the red wavelength region may have a greater optical path length. Accordingly, self-absorption of light Lᵣ in the red wavelength region may easily occur in the first wavelength conversion material 1171r. Due to the self-absorption, it may be difficult to extract a sufficient amount of light Lᵣ in the red wavelength region.

In contrast, in the red conversion layer 117r, the scattering of light Lᵣ in the red wavelength region may be suppressed, and accordingly, the self-absorption of light Lᵣ in the red wavelength region may hardly occur. Therefore, more light Lᵣ in the red wavelength region may be extracted than in the red conversion layer 1000r. For example, as calculated from the simulation result shown in FIG. 4, about 1.3 times the amount of light Lᵣ in the red wavelength region may be extracted compared to the red conversion layer 1000r. The same may be true for the green conversion layer 117g. In the display apparatus 100, more light in the red wavelength region and more light in the green wavelength region may be extracted, thereby making it possible to suppress power consumption.

In addition, in the display apparatus 100, the particle size D1 of the first single-crystal silicon particle 1172r included in the red conversion layer 117r and the particle size D2 of the second single-crystal silicon particle 1172g included in the green conversion layer 117g may be different from each other. Accordingly, the single-crystal silicon particle having a particle size appropriate for each of the red conversion layer 117r and the green conversion layer 117g may be used.

In detail, in the single-crystal silicon particle, wavelength selectivity of the scattering can vary depending on the particle size. If the particle size of single crystal silicon particles decreases, a scattering peak wavelength tends to shift toward a shorter wavelength. Accordingly, the single-crystal silicon particle having a particle size appropriate for each of the red conversion layer 117r and the green conversion layer 117g may be used, thereby making it possible to extract more light in both the red wavelength region and the green wavelength region.

Hereinafter, a modified example of the display apparatus 100 described in an above-described embodiment is described. In addition, hereinafter, a detailed description of each component the same as that of the display apparatus 100 described in an above-described embodiment can be omitted to avoid a redundant description thereof.

### Modified Example

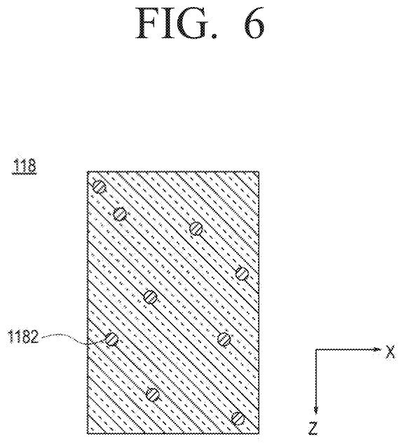

FIG. 6 shows an example of a configuration of a transparent layer 118 included in a display apparatus 100 according to the modified example. The transparent layer 118 may include a plurality of third single-crystal silicon particles 1182. Except for this point, the display apparatus 100 according to the modified example may have the same configuration as the display apparatus 100 described in an above-described embodiment.

The plurality of third single-crystal silicon particles 1182 may be dispersed in the transparent layer 118. The third single-crystal silicon particles 1182 may include the single crystal silicon. The third single-crystal silicon particles 1182 may have, for example, the spherical shape. A particle size D3 corresponding to a particle size distribution peak of the plurality of third single-crystal silicon particle 1182 may be different from, for example, the size D1 or the size D2. The size D3 may be the same as the size D1 or the size D2. The third single-crystal silicon particle 1182 included in the transparent layer 118 may have, for example, a concentration of 0.5 wt % to 15 wt %.

In the display apparatus 100 according to the modified example, the red conversion layer 117r may include the plurality of first single-crystal silicon particles 1172r, and the green conversion layer 117g may include the plurality of second single-crystal silicon particles 1172g, similar to those described in an above-described embodiment. Accordingly, more light in the red wavelength region may be extracted from the red pixel 10r and more light in the green wavelength region may be extracted from the green pixel 10g, respectively.

The configuration of the display apparatus 100 described above describes a main configuration in describing features of the display apparatus 100 according to an above-described embodiment and the modified example. The display apparatus 100 is not limited to the above-described configuration, and may be variously improved within the scope of the claims. In addition, the present disclosure does not exclude configurations included in a general dis play apparatus.

For example, although the light source 122 is described as emitting light in the blue wavelength region, the light source 122 may emit light in a different wavelength region. Alternatively, the light source 122 may be disposed in each of the red pixel 10r, the green pixel 10g, and the blue pixel 10b, emitting light in different wavelength regions.

In addition, although an above-described embodiment or the like describes an example in which the light source 122 includes the micro LED, the light source 122 may include another light-emitting element. For example, the light source 122 may include a general-sized LED, or may include an organic electroluminescence (EL) or an inorganic EL. The display apparatus 100 may include a liquid crystal display element.

In addition, although an above-described embodiment or the like describes an example in which the display apparatus 100 includes the red conversion layer 117r and the green conversion layer 117g, the red conversion layer 117r and the green conversion layer 117g may be applied to another apparatus such as a lighting apparatus. In other words, the light-emitting element according to the present disclosure may be applied to a apparatus other than the display apparatus. For example, the light-emitting element may be applied to the lighting apparatus.

In addition, although an above-described embodiment or the like describes an example in which the blue pixel 10b includes the transparent layer 118, the blue pixel 10b may include a wavelength conversion layer.

According to an embodiment, According to an aspect of the disclosure, there is provided a light-emitting element including: a light source configured to emit light in a first wavelength region; and a wavelength conversion layer including: a wavelength conversion material configured to convert light in the first wavelength region into light in a second wavelength region; and a plurality of single-crystal silicon particles configured to scatter light in the first wavelength region.

According to an embodiment, a display apparatus includes: a light source provided in each of a first pixel and a second pixel, each light source being configured to emit light in a first wavelength region; a first wavelength conversion layer provided in the first pixel, and including a first wavelength conversion material configured to convert light in the first wavelength region into light in a second wavelength region, and a plurality of first single-crystal silicon particles configured to scatter light in the first wavelength region; and a second wavelength conversion layer provided in the second pixel, and including a second wavelength conversion material configured to convert light in the first wavelength region into light in a third wavelength region different from the second wavelength region, and a plurality of second single-crystal silicon particles configured to scatter light in the first wavelength region.

According to an embodiment, a lighting apparatus includes: a first wavelength conversion layer provided in a first pixel, and including a first wavelength conversion material configured to convert light in a first wavelength region into light in a second wavelength reg ion, and a plurality of first single-crystal silicon particles configured to scatter light in the first wavelength region; and a second wavelength conversion layer provided in a second pixel, and including a second wavelength conversion material configured to convert light in the first wavelength region into light in a third wavelength region different from the second wavelength region, and a plurality of second single-crystal silicon particles configured to scatter light in the first wavelength region.

In addition, although an above-described embodiment or the like describes an example in which light in the red wavelength region, light in the green wavelength region, and light in the blue wavelength region are extracted from the display apparatus 100, the wavelength region of light extracted from the display apparatus 100 is not limited thereto.

What is claimed is:

1. A light-emitting element comprising:
a light source configured to emit light in a first wavelength region; and
a wavelength conversion layer comprising:
a wavelength conversion material configured to convert light in the first wavelength region into light in a second wavelength region; and
a plurality of single-crystal silicon particles configured to scatter light in the first wavelength region.

2. The light-emitting element as claimed in claim 1, wherein the second wavelength region is a red wavelength region, and
wherein a single-crystal silicon particle, from among the plurality of single-crystal silicon particles, has a size greater than or equal to 90 nm o and less than or equal to 130 nm.

3. The light-emitting element as claimed in claim 1, wherein the second wavelength region is a green wavelength region, and
wherein a single-crystal silicon particle, from among the plurality of single-crystal silicon particles, has a size greater than or equal to 80 nm and less than or equal to 110 nm.

4. The light-emitting element as claimed in claim 1, wherein the first wavelength region is a blue wavelength region.

5. The light-emitting element as claimed in claim 1, wherein the wavelength conversion material comprises at least one of quantum dots or phosphors.

6. A display apparatus comprising:
a light source provided in each of a first pixel and a second pixel, each light source being configured to emit light in a first wavelength region;
a first wavelength conversion layer provided in the first pixel, and comprising a first wavelength conversion material configured to convert light in the first wavelength region into light in a second wavelength region, and a plurality of first single-crystal silicon particles configured to scatter light in the first wavelength region; and
a second wavelength conversion layer provided in the second pixel, and comprising a second wavelength conversion material configured to convert light in the first wavelength region into light in a third wavelength region different from the second wavelength region, and a plurality of second single-crystal silicon particles configured to scatter light in the first wavelength region.

7. The display apparatus as claimed in claim 6, wherein a particle size D1 corresponding to a first particle size distribution peak of the plurality of first single-crystal silicon particles and a particle size D2 corresponding to a second particle size distribution peak of the plurality of second single-crystal silicon particles are different from each other.

8. The display apparatus as claimed in claim 7, wherein a peak wavelength in the third wavelength region is shorter than a peak wavelength in the second wavelength region, and
wherein the particle size D2 is smaller than the particle size D1.

9. The display apparatus as claimed in claim 8, wherein the first wavelength region is a blue wavelength region, the second wavelength region is a red wavelength region, and the third wavelength region is a green wavelength region.

10. The display apparatus as claimed in claim 6, wherein a light source is provided in a third pixel, further comprising a plurality of third single-crystal silicon particles for scattering light in the first wavelength region.

11. The display apparatus as claimed in claim 6, wherein each light source comprises a micro light-emitting diode (LED).

12. A lighting apparatus comprising:
a first wavelength conversion layer provided in a first pixel, and comprising a first wavelength conversion material configured to convert light in a first wavelength region into light in a second wavelength region, and a plurality of first single-crystal silicon particles configured to scatter light in the first wavelength region; and
a second wavelength conversion layer provided in a second pixel, and comprising a second wavelength conversion material configured to convert light in the first wavelength region into light in a third wavelength region different from the second wavelength region, and a plurality of second single-crystal silicon particles configured to scatter light in the first wavelength region.

13. The lighting apparatus as claimed in claim 12, further comprising a transparent layer comprising a plurality of third single-crystal silicon particles.

14. The lighting apparatus as claimed in claim 12, wherein a particle size D1 corresponding to a first particle size distribution peak of the plurality of first single-crystal silicon particles and a particle size D2 corresponding to a second particle size distribution peak of the plurality of second single-crystal silicon particles are different from each other.

15. The lighting apparatus as claimed in claim 14, wherein a peak wavelength in the third wavelength region is shorter than a peak wavelength in the second wavelength region, and
wherein the particle size D2 is smaller than the particle size D1.

16. The lighting apparatus as claimed in claim 15, wherein the first wavelength region is a blue wavelength region, the second wavelength region is a red wavelength region, and the third wavelength region is a green wavelength region.

17. The lighting apparatus as claimed in claim 12, further comprising a plurality of third single-crystal silicon particles for scattering light in the first wavelength region.
